(19) United States
(12) Patent Application Publication
(10) Pub. No.: US 2006/0065980 A1
(43) Pub. Date: Mar. 30, 2006

(54) Semiconductor device

(76) Inventor: Moto Yabuki, Tokyo (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/271,858

(22) Filed: Nov. 14, 2005

Related U.S. Application Data
(62) Division of application No. 11/042,176, filed on Jan. 26, 2005.
Application No. 11/042,176 is a division of application No. 10/682,110, filed on Oct. 10, 2003, now abandoned.

(30) Foreign Application Priority Data
Oct. 11, 2002 (JP) 2002-298506

(51) Int. Cl. H01L 23/52

(52) U.S. Cl. 257/758

(57) ABSTRACT

Disclosed is a semiconductor device comprising an underlying film, a first electrode formed on the underlying film, a first dielectric film formed on the first electrode, a second electrode formed on the first dielectric film, and a first interconnect including a first conductive portion extending in a stack direction of the first electrode, the first dielectric film and the second electrode, a side surface of the first conductive portion being in contact with one of the first electrode and the second electrode.

### CROSS-REFERENCE TO RELATED APPLICATIONS

This application is based upon and claims the benefit of priority from the prior Japanese Patent Application No. 2002-298506, filed Oct. 11, 2002, the entire contents of which are incorporated herein by reference.

### BACKGROUND OF THE INVENTION

1. Field of the Invention

The present invention relates to a semiconductor device having a capacitor.

2. Description of the Related Art

Nonvolatile memories (FeRAMs) have been researched and developed which use a ferroelectric film such as a PZT film (Pb(Zr,Ti)O₃ film), as a dielectric film for a capacitor.

FIG. 10 is a sectional view showing an example of the configuration of a ferroelectric memory according to the prior art. Reference numeral 11 denotes an interlayer insulating film such as a silicon oxide film. Reference numerals 12 and 13 denote a silicon nitride film and a silicon oxide film, respectively. A ferroelectric capacitor is formed on the silicon oxide film 13, the ferroelectric capacitor comprising a bottom electrode 21, a ferroelectric film 22, and a top electrode 23. The capacitor is covered with a silicon oxide film 31. A silicon oxide film 32 is formed on the silicon oxide film 31. An interconnect including conductive portions 41a, 41b, and 41c is connected to the bottom electrode 21 of the capacitor. An interconnect including conductive portions 42a, 42b, and 42c is connected to the top electrode 23. These interconnects are connected to transistors, interconnects, or the like (not shown) formed in lower region.

In the conventional ferroelectric memory, the interconnect connected to the bottom electrode 21 or top electrode 23 is composed of a conductive portion (41a, 42a) extending in a vertical direction, a conductive portion (41c, 42c) extending in a horizontal direction, and a conductive portion (41b, 42b) extending in the vertical direction. Consequently, the interconnects disadvantageously require a large area, thus making it difficult to achieve a fine-grained structure. Furthermore, manufacturing steps for forming interconnects are complicated.

As a known technique, the structure of a ferroelectric memory is described in, for example, “A Fully Planarized 8M bit Ferroelectric RAM with Chain Cell Structure”, Digest of Tech. papers 2001 Symp. on VLSI Tech., p. 113 to 114, T. Ozaki et al. However, this structure is essentially the same as the example described above and thus has the same problems. Specifically, the interconnects require a large area, thus making it difficult to achieve a fine-grained structure. Furthermore, manufacturing steps for forming interconnects are complicated.

Thus, with the prior art, the interconnects disadvantageously require a large area, and it is difficult to provide a semiconductor device of a fine-grained structure.

### BRIEF SUMMARY OF THE INVENTION

A semiconductor device according to a first aspect of the present invention comprises: an underlying film; a first electrode formed on the underlying film; a first dielectric film formed on the first electrode; a second electrode formed on the first dielectric film; and a first interconnect including a first conductive portion extending in a stack direction of the first electrode, the first dielectric film and the second electrode, a side surface of the first conductive portion being in contact with one of the first electrode and the second electrode.

A semiconductor device according to a second aspect of the present invention comprises: an underlying film; a first electrode formed on the underlying film; a dielectric film formed on the first electrode; a second electrode formed on the dielectric film; and an interconnect connected to the second electrode and including a first conductive portion extending in a stack direction of the first electrode, the dielectric film and the second electrode, and a second conductive portion which is formed of a material different from those of the second electrode and the first conductive portion and which connects the second electrode to the first conductive portion, a side surface of the first conductive portion being in contact with the second conductive portion.

### BRIEF DESCRIPTION OF THE SEVERAL VIEWS OF THE DRAWING

FIGS. 1A and 1B are sectional views schematically showing manufacturing steps for a semiconductor device according to a first embodiment of the present invention;

FIGS. 2A and 2B are sectional views schematically showing manufacturing steps for a semiconductor device according to a second embodiment of the present invention;

FIGS. 3A and 3B are sectional views schematically showing manufacturing steps for a semiconductor device according to a third embodiment of the present invention;

FIGS. 4A and 4B are sectional views schematically showing manufacturing steps for a semiconductor device according to a fourth embodiment of the present invention;

FIGS. 5A and 5B are sectional views schematically showing manufacturing steps for a semiconductor device according to a fifth embodiment of the present invention;

FIGS. 6A and 6B are sectional views schematically showing manufacturing steps for a semiconductor device according to a sixth embodiment of the present invention;

FIGS. 7A and 7B are sectional views schematically showing manufacturing steps for a semiconductor device according to a seventh embodiment of the present invention;

FIGS. 8A and 8B are sectional views schematically showing manufacturing steps for a semiconductor device according to an eighth embodiment of the present invention;

FIG. 9 is a sectional view schematically showing the configuration of a semiconductor device according to a ninth embodiment of the present invention; and

FIG. 10 is a sectional view schematically showing the configuration of a semiconductor device according to the prior art.

### DETAILED DESCRIPTION OF THE INVENTION

Embodiments of the present invention will be described with reference to the drawings.

### EMBODIMENT 1

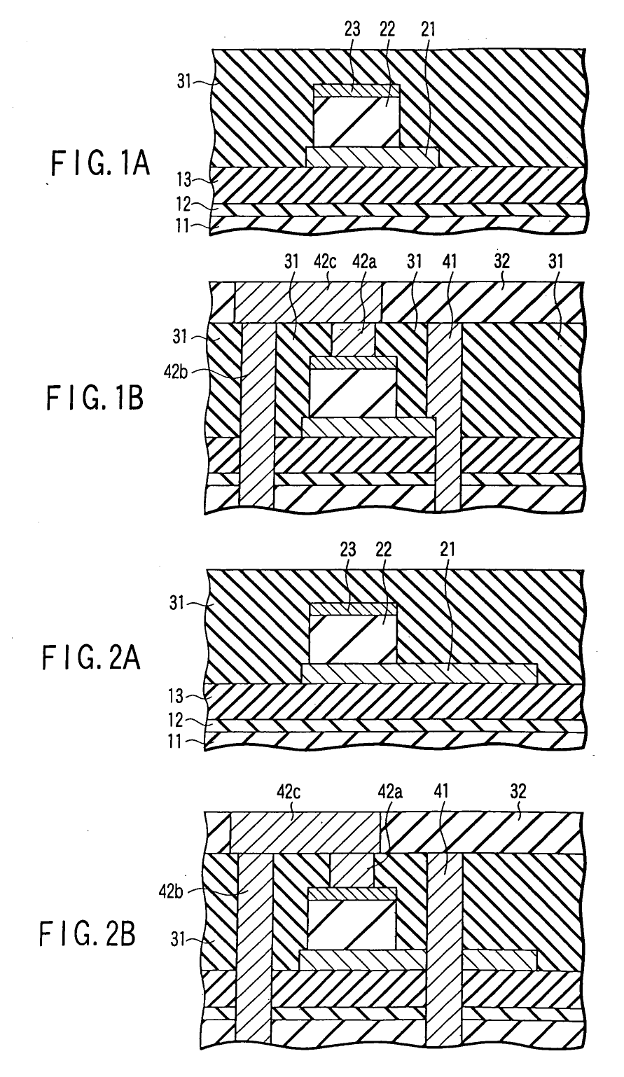

FIGS. 1A and 1B are sectional views schematically showing manufacturing steps for a semiconductor device (ferroelectric memory) according to a first embodiment of the present invention.

First as shown in FIG. 1A, an interlayer insulating film 11 such as a silicon oxide film (SiO₂ film) is formed on a semiconductor substrate (not shown) on which a MIS transistor (not shown) or the like is formed. Subsequently, a silicon oxide film (SiN film) 12 is formed by low pressure CVD. Furthermore, a silicon oxide film 13 is formed by low pressure CVD using TEOS. Subsequently, a ferroelectric capacitor is formed on the silicon oxide film 13, the ferroelectric capacitor comprising a bottom electrode 21, a ferroelectric film 22 on the bottom electrode 21, and a top electrode 23 on the ferroelectric film 22. The bottom electrode 21 and the top electrode 23 are formed of, for example, a platinum (Pt) film, an iridium (Ir) film, or an IrO₂ film. The ferroelectric film 22 is formed of, for example, a PZT film (Pb(Zr,Ti)O₃ film). Moreover, a silicon oxide film 31 is formed all over the surfaces of the silicon oxide film 13 and the ferroelectric capacitor by plasma CVD using TEOS.

Then, as shown in FIG. 1B, connecting holes are formed through the silicon oxide film 31, the silicon oxide film 13, the silicon nitride film 12, and the interlayer insulating film 11 by RIE or the like. Subsequently, an Al film is formed on the entire surface as a metal film. Moreover, an extra metal film is removed by CMP to leave the metal film in each connecting hole. This results in a conductive portion (plug) 41 connected to the bottom electrode 21, a conductive portion 42a connected to the top electrode, and a conductive portion (plug) 42b. Before the Al film is formed, a TiN film or the like may be formed as a barrier metal film in order to suppress the reaction between the Al film and the electrode.

Then, a silicon oxide film 32 is formed on the entire surface. Moreover, a trench is formed in the silicon oxide film 32. Subsequently, an Al film is formed on the entire surface as a metal film. Moreover, an extra metal film is removed by CMP to leave the metal film in the trench. This results in a conductive portion 42c connecting the conductive portion 42a and the conductive portion 42b together.

Thus, a structure is obtained in which an interconnect (wiring) comprising the conductive portion 41 is connected to the bottom electrode 21 of the capacitor and in which an interconnect comprising the conductive portions 42a, 42b, and 42c is connected to the top electrode 23. These interconnects are connected to, for example, transistors or interconnects (FEOL: Front End Of Line), or the like formed in lower region.

As seen in FIG. 1B, in the present embodiment, the conductive portion (interconnect) 41 is in contact with an end of the bottom electrode 21. That is, a side of the interconnect 41 is in contact with a side of the bottom electrode 21. The interconnect 41 is also in contact with the top surface of the bottom electrode 21. These contact portions allow the bottom electrode 21 and the interconnect 41 to be electrically connected together.

Thus, in the present embodiment, the bottom electrode 21 and the interconnect 41 are connected together using the end of the bottom electrode 21. This sharply reduces the area required for the interconnects compared to the prior art. It is therefore possible to provide a semiconductor device of a fine-grained structure.

### EMBODIMENT 2

FIGS. 2A and 2B are sectional views schematically showing manufacturing steps for a semiconductor device (ferroelectric memory) according to a second embodiment of the present invention. Basic arrangements and manufacturing steps are similar to those of the first embodiment. Accordingly, components corresponding to those shown in FIGS. 1A and 1B are denoted by the same reference numerals, with their detailed description omitted. For the other embodiments, the description described in the first embodiment is also omitted.

In the present embodiment, as shown in FIG. 2B, the interconnect (conductive portion) 41 penetrates the bottom electrode 21. The sides of the interconnect 41 are in contact with the inner sides of the bottom electrode 21. Specifically, the interconnect 41 is formed by forming a connecting hole through the bottom electrode 21 by RIE or the like and burying a metal film such as an Al film in the connecting hole.

Thus, in the present embodiment, the bottom electrode 21 and the interconnect 41 are connected together by allowing the bottom electrode 41 to penetrate the bottom electrode 21. Consequently, as in the case with the first embodiment, the area required for the interconnects can be sharply reduced compared to the prior art. It is therefore possible to provide a semiconductor device of a fine-grained structure.

### EMBODIMENT 3

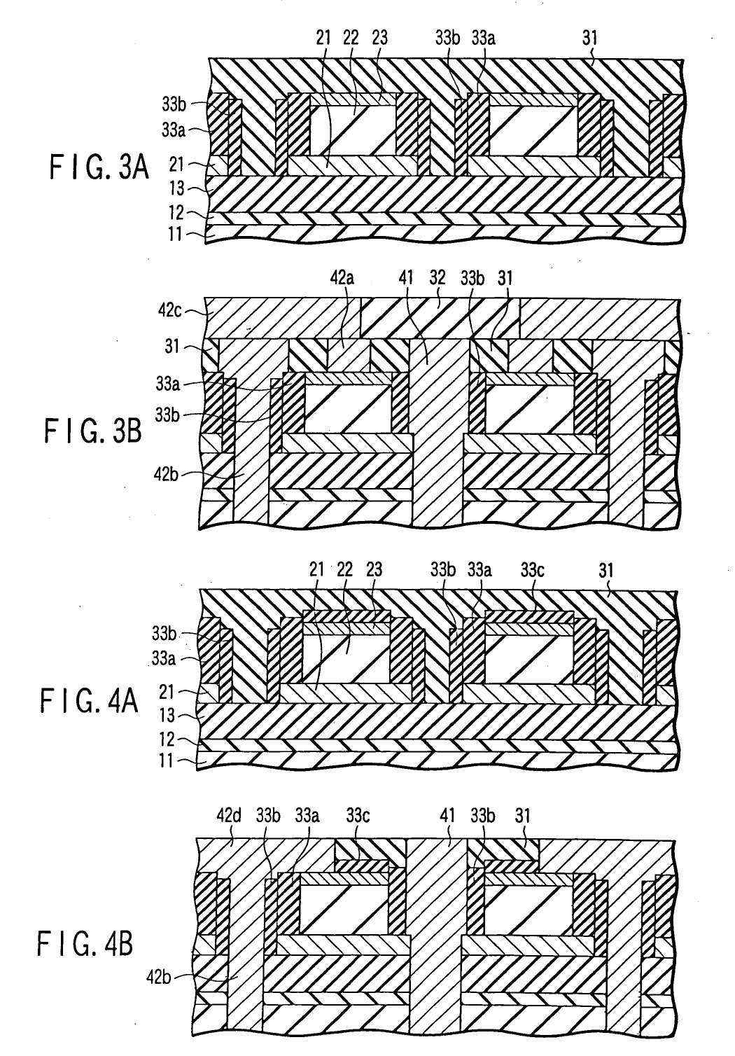

FIGS. 3A and 3B are sectional views schematically showing manufacturing steps for a semiconductor device (ferroelectric memory) according to a third embodiment of the present invention.

First, as shown in FIG. 3A, the interlayer insulating film 11, the silicon nitride film 12, and the silicon oxide film 13 are formed as in the case with the first embodiment. Subsequently, a ferroelectric capacitor is formed on the silicon oxide film 13, the ferroelectric capacitor having a stack structure of the bottom electrode 21, the ferroelectric film 22, and the top electrode 23. However, in the present embodiment, a sidewall insulating film 33a formed of a silicon nitride film is formed on the sides of the ferroelectric film 22 and the top electrode 23. Specifically, after the ferroelectric film 22 and the top electrode 23 have been patterned, a silicon nitride film is formed on the entire surface. Moreover, RIE is carried out. Thus, a sidewall insulating film 33a is formed on the sides of the ferroelectric film 22 and the top electrode 23. Furthermore, the pattern of the bottom electrode 21 is formed. Subsequently, a silicon nitride film is formed on the entire surface. Moreover, RIE is carried out. Thus, a sidewall insulating film 33b formed of the silicon nitride film is formed on the sides of the bottom electrode 21 and the sidewall insulating film 33a. Subsequently, the silicon oxide film 31 is formed on the entire surface.

Then, as shown in FIG. 3B, a part of the silicon oxide film 31 and others is removed by RIE or the like to form connecting holes. At this time, the connecting hole used to form the conductive portion (interconnect) 41 is formed by etching the sidewall insulating films 33a and 33b using a photo resist as a mask. Thus, an end of the bottom electrode is exposed. On the other hand, the connecting hole used to form the conductive portion 42b is formed by selectively-etching the silicon oxide film 31 and others with respect to the sidewall insulating films 33a and 33b without using a photo resist. Thus, the end of the bottom electrode is prevented from being exposed. Subsequently, an Al film is formed on the entire surface as a metal film. Moreover, an extra metal film is removed by CMP to leave the metal film in each connecting hole. This results in the conductive portion 41 connected to the bottom electrode 21, the conductive portion 42a connected to the top electrode 23, and the conductive portion 42b. As in the case with the first embodiment, a barrier metal film may be formed before the Al film is formed.

The subsequent steps are similar to those of the first embodiment. An Al film is buried in a trench formed in the silicon oxide film 32 to form a conductive portion 42c connecting the conductive portion 42a and the conductive portion 42b together.

Thus, a structure is obtained in which an interconnect formed of the conductive portion 41 is connected to the bottom electrode 21 of the capacitor and in which an interconnect comprising the conductive portions 42a, 42b, and 42c is connected to the top electrode 23.

In the present embodiment, the bottom electrode 21 and the interconnect 41 are connected together using the end of the bottom electrode 21 as in the case with the first embodiment. This sharply reduces the area required for the interconnects compared to the prior art. It is therefore possible to provide a semiconductor device of a fine-grained structure. Furthermore, in the present embodiment, the sidewall insulating films 33a and 33b are formed on the sides of the capacitor. This serves to reduce the distance between adjacent capacitors, thus providing a semiconductor device of a finer-grained structure.

### EMBODIMENT 4

FIGS. 4A and 4B are sectional views schematically showing manufacturing steps for a semiconductor device (ferroelectric memory) according to a fourth embodiment of the present invention. Basic arrangements and manufacturing steps are similar to those of the third embodiment. Accordingly, components corresponding to those shown in FIGS. 3A and 3B are denoted by the same reference numerals, with their detailed description omitted.

In the present embodiment, in the step shown in FIG. 4A, the sidewall insulating films 33a and 33b are not only formed but an upper insulating film 33c is also formed on the top surface of the top electrode 23. Specifically, after the ferroelectric film 22 and the top electrode 23 have been patterned, a silicon nitride film is formed on the entire surface. Moreover, RIE is carried out using a photo resist as a mask. Thus, the sidewall insulating film 33a is formed on the sides of the ferroelectric film 22 and the top electrode 23. Furthermore, the upper insulating film 33c is formed on the top surface of the top electrode 23. Subsequently, the sidewall insulating film 33b is formed using a method similar to that of the third embodiment.

In the step shown in FIG. 4B, an Al film is simultaneously buried in the connecting holes and in the trench formed by removing the silicon oxide film 31 and the upper insulating film 33c. Thus, a structure is obtained in which an interconnect formed of the conductive portion 41 is connected to the bottom electrode 21 of the capacitor and in which an interconnect comprising the conductive portion 42b and a conductive portion 42d is connected to the top electrode 23.

With this structure, the present embodiment can also produce effects similar to those of the third embodiment.

### EMBODIMENT 5

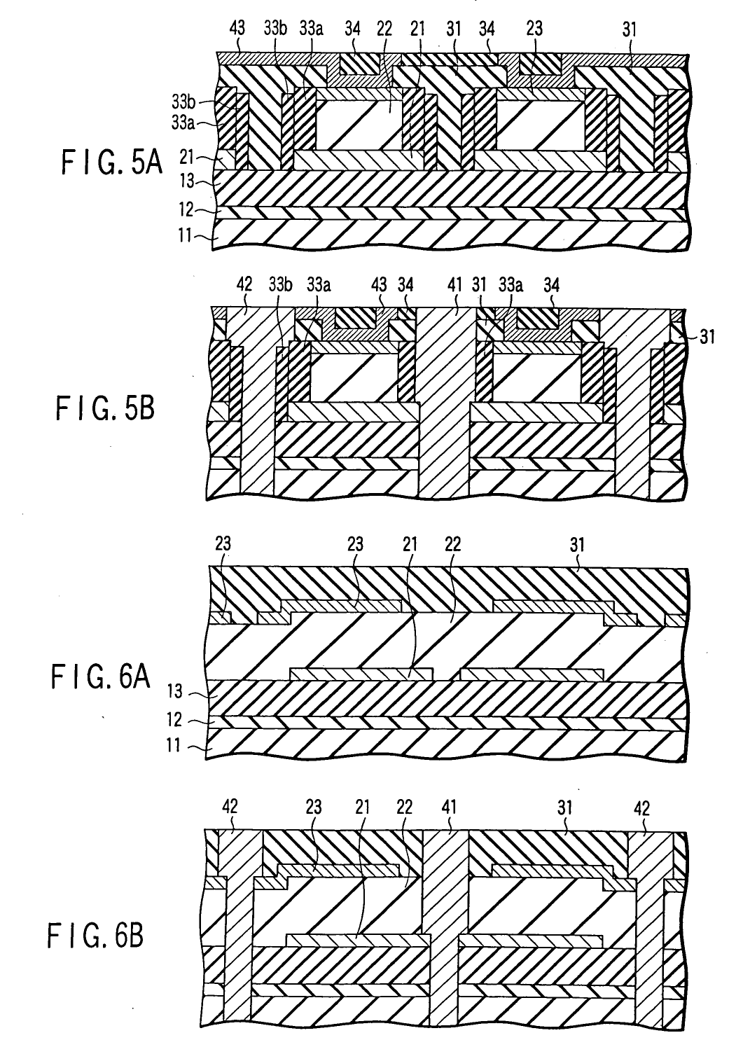

FIGS. 5A and 5B are sectional views schematically showing manufacturing steps for a semiconductor device (ferroelectric memory) according to a fifth embodiment of the present invention. Basic arrangements and manufacturing steps are similar to those of the third embodiment. Accordingly, components corresponding to those shown in FIGS. 3A and 3B are denoted by the same reference numerals, with their detailed description omitted.

In the present embodiment, in the step shown in FIG. 5A, the capacitor, the sidewall insulating film, and the interlayer insulating film are formed as in the case with the third embodiment. Subsequently, a hole is formed in the interlayer insulating film 31 so as to reach the top electrode 23. Subsequently, a conductive film is formed on the entire surface. Moreover, the conductive film is patterned to form a conductive portion 43 connected the top electrode 23. The conductive portion 43 is made of a material that does not cause an alloying reaction between the top electrode 23 and an Al film formed during the step shown in FIG. 5B, e.g. a conductive material such as TiN. Subsequently, a silicon oxide film 34 is formed on the entire surface. Moreover, the silicon oxide film 34 is flattened by CMP and thus buried in concave portions.

In the step shown in FIG. 5B, the conductive portions 41 and 42, formed of a metal film such as an Al film, are formed using a method similar to that of the third embodiment. However, in the present embodiment, when the connection holes are formed, the conductive portion 43 is partly etched. Accordingly, by burying a conductive film such as a TiN film in the connecting holes, a side of the conductive portion 42 is contacted with a side of the conductive portion 43 to connect the conductive portions 42 and 43 electrically together.

Thus, a structure is obtained in which an interconnect formed of the conductive portion 41 is connected to the bottom electrode 21 of the capacitor and in which an interconnect comprising the conductive portion 42 and a conductive portion 43 is connected to the top electrode 23.

The present embodiment can also produce effects similar to those of the first and third embodiment. Moreover, since the side of the conductive portion 43 is in contact with the side of the conductive portion 42, it is possible to reduce the area for the interconnect connected to the top electrode 23. Furthermore, the top electrode 23 and the conductive portion 42 are connected together using the conductive portion 43, formed of a material (barrier metal material) such as TiN. This surely prevents the reaction between the top electrode 23 and the conductive portion 42.

### EMBODIMENT 6

FIGS. 6A and 6B are sectional views schematically showing manufacturing steps for a semiconductor device (ferroelectric memory) according to a sixth embodiment of the present invention.

First, as shown in FIG. 6A, the interlayer insulating film 11, the silicon nitride film 12, and the silicon oxide film 13 are formed on a semiconductor substrate (not shown) on which a MIS transistor (not shown) or the like is formed, as in the case with the first embodiment. Then, an electrode film is formed on the silicon oxide film 13 and then patterned to form the bottom electrode 21 of the ferroelectric capacitor. Subsequently, the ferroelectric film 22 is formed on the entire surface. Moreover, an electrode film is formed on the entire surface. The electrode film is patterned to form the top electrode 23 of the capacitor. Subsequently, the silicon oxide film 31 is formed by plasma CVD using TEOS.

Then, as shown in FIG. 6B, connecting holes are formed through the interlayer insulating film 11, the silicon nitride film 12, the silicon oxide film 13, the ferroelectric film 22, and the silicon oxide film 31 by RIE or the like. Subsequently, an Al film is formed on the entire surface as a metal film. Moreover, an extra metal film is removed by CMP to leave the metal film in each connecting hole. This results in the conductive portion (interconnect) 41 connected to the bottom electrode 21 and the conductive portion (interconnect) 42 connected to the top electrode.

As seen in FIG. 6B, in the present embodiment, the conductive portion (interconnect) 41 is in contact with the end of the bottom electrode 21, as described in the first embodiment. The conductive portion (interconnect) 42 is in contact with an end of the top electrode 23. Therefore, as in the case with the first embodiment, the area required for the interconnects can be sharply reduced to provide a semiconductor device of a fine-grained structure.

Furthermore, in the present embodiment, the interconnect 41 is formed so as to pass through the gap between a pair of adjacent bottom electrodes 21. The pair of bottom electrodes 21 is connected to the common interconnect 41. Likewise, the interconnect 42 is formed so as to pass through the gap between a pair of adjacent top electrodes 23. The pair of top electrodes 23 is connected to the common interconnect 42. Furthermore, the interconnect 41 is arranged so as to pass through the gap between adjacent top electrodes 23 that do not form a pair. The interconnect 41 is not connected to these top electrodes 23. Likewise, the interconnect 42 is arranged so as to pass through the gap between adjacent bottom electrodes 21 that do not form a pair. The interconnect 42 is not connected to these bottom electrodes 21. Therefore, the distance between adjacent capacitors can be effectively reduced to provide a semiconductor device of a fine-grained structure.

### EMBODIMENT 7

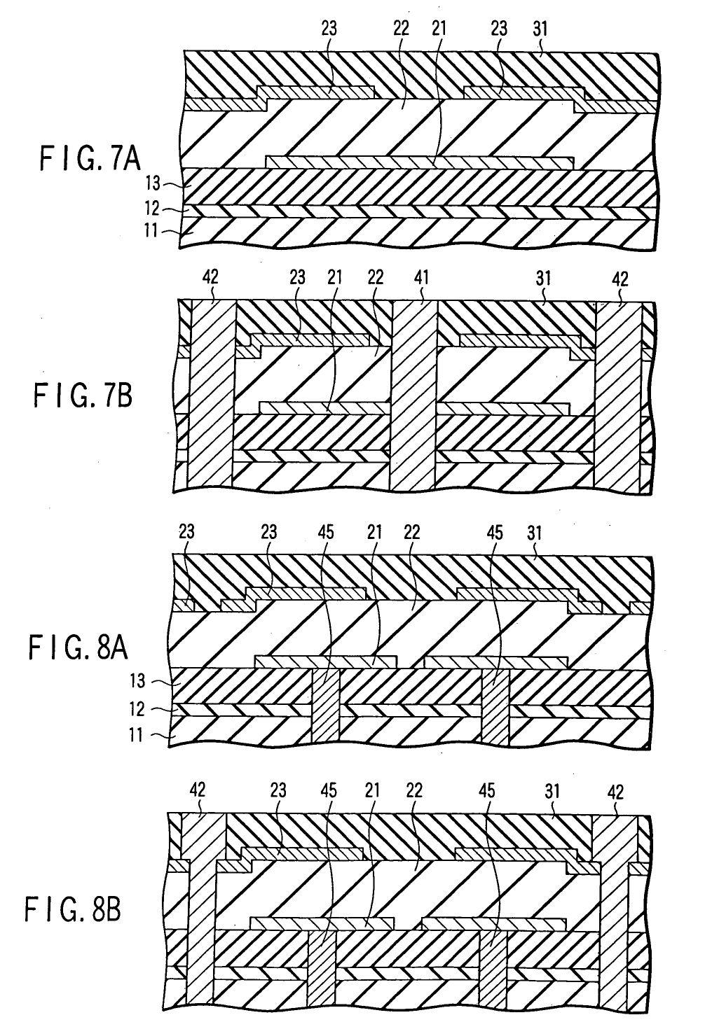

FIGS. 7A and 7B are sectional views schematically showing manufacturing steps for a semiconductor device (ferroelectric memory) according to a seventh embodiment of the present invention. Basic arrangements and manufacturing steps are similar to those of the sixth embodiment. Accordingly, components corresponding to those shown in FIGS. 6A and 6B are denoted by the same reference numerals, with their detailed description omitted.

In the present embodiment, as shown in FIG. 7B, the interconnect 41 penetrates the bottom electrode 21, and its sides are in contact with the inner sides of the bottom electrode 21. Similarly, the interconnect 42 penetrates the top electrode 23, and its sides are in contact with the inner sides of the top electrode 23. Furthermore, the interconnect 41 is arranged so as to pass through the gap between the adjacent top electrodes 23, and is not connected to these top electrodes 23. Similarly, the interconnect 42 is arranged so as to pass through the gap between the adjacent bottom electrodes 21, and is not connected to these bottom electrodes 21.

With these arrangements, the distance between adjacent capacitors can be effectively reduced to provide a semiconductor device of a fine-grained structure, as in the case with the sixth embodiment.

### EMBODIMENT 8

FIGS. 8A and 8B are sectional views schematically showing manufacturing steps for a semiconductor device (ferroelectric memory) according to an eighth embodiment of the present invention. Basic arrangements and manufacturing steps are similar to those of the sixth embodiment. Accordingly, components corresponding to those shown in FIGS. 6A and 6B are denoted by the same reference numerals, with their detailed description omitted.

The present embodiment relates to a ferroelectric memory having what is called a “COP structure”. Specifically, in the step shown in FIG. 8A, a plug (for example, a W plug) 45 is formed before a capacitor is formed. This plug is an interconnect connected to the bottom electrode 21. In the step shown in FIG. 8B, the conductive portion (interconnect) 42 is formed so as to contact with the end of the top electrode 23, as in the case with the sixth embodiment. Alternatively, the interconnect 42 may penetrate the top electrode 23 as in the case with the seventh embodiment.

Thus, in the present embodiment, the COP structure is employed for the bottom electrode, while a structure such as that of the sixth or seventh embodiment is employed for the top electrode. With this structure, the area required for the interconnects can be sharply reduced to provide a semiconductor device of a fine-grained structure.

### EMBODIMENT 9

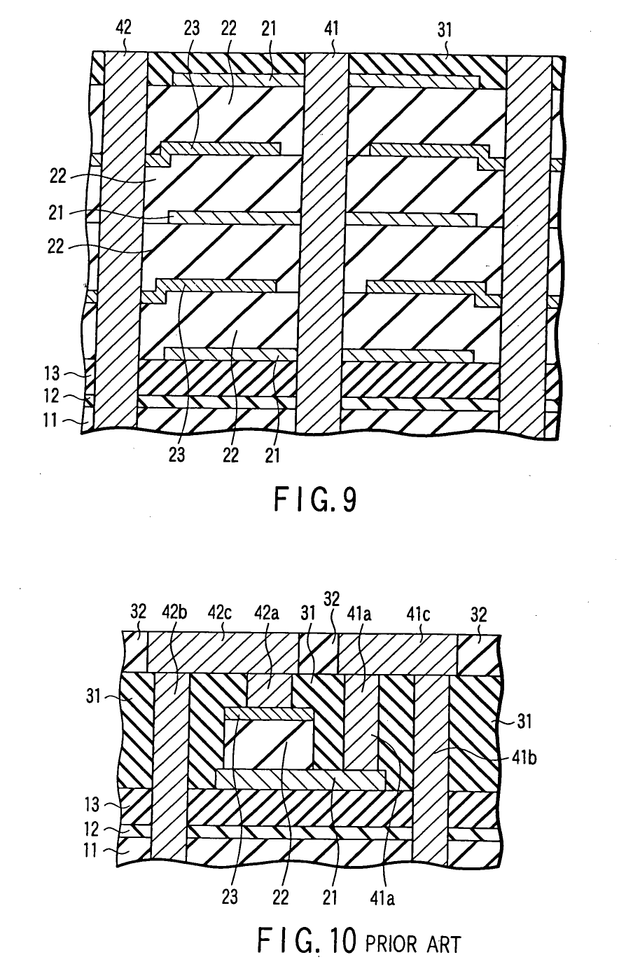

FIG. 9 is a sectional view schematically showing the configuration of a semiconductor device (ferroelectric memory) according to a ninth embodiment of the present invention.

As seen in FIG. 9, in the present embodiment, a plurality of capacitor structures such as the one shown in the seventh embodiment are stacked in the vertical direction. That is, a plurality of bottom electrodes 21 of the same shape are stacked in the same area and are all connected together by the same interconnect 41. Likewise, a plurality of top electrodes 23 of the same shape are stacked in the same area and are all connected together by the same interconnect 42. The bottom electrodes 21 and the top electrodes 23 are alternately stacked. The ferroelectric film 22 is formed between the adjacent electrodes. The areas between the electrodes adjacent to each other in the stack direction function as capacitors.

Here, for convenience, the electrode 21 is the bottom electrode, whereas the electrode 23 is the top electrode. However, as is apparent from the above arrangements, a bottom electrode in one capacitor functions as a top electrode for the capacitor located bellow. Similarly, a top electrode in one capacitor functions as a bottom electrode for the capacitor located above. Furthermore, in the description, a structure such as the one shown in the seventh embodiment is assumed to be basic. However, a structure such as the one shown in the sixth embodiment can be used as a basic structure.

The present embodiment can produce effects similar to those of the sixth and seventh embodiments. Moreover, the plurality of stacked bottom electrodes 21 are connected together by the same interconnect 41, and the plurality of stacked top electrodes 23 are connected together by the same interconnect 42. Therefore, the area for the interconnects can be efficiently reduced using the simple manufacturing steps.

In the first to ninth embodiments, an MIM (Metal/Insulator/Metal) capacitor structure, such as a TiN/SiN/TiN structure, may me used in place of a ferroelectric capacitor structure.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising:
an underlying film;
a first electrode formed on the underlying film;
a first dielectric film formed on the first electrode;
a second electrode formed on the first dielectric film;
a first interconnect including a first conductive portion extending in a stack direction of the first electrode, the first dielectric film and the second electrode, a side surface of the first conductive portion being in contact with the first electrode; and
a second interconnect including a second conductive portion extending in the stack direction, a side surface of the second conductive portion being in contact with the second electrode.

2. The semiconductor device according to claim 1, wherein the first conductive portion is in contact with a side surface and a top surface of the first electrode and the second conductive portion is in contact with a side surface and a top surface of the second electrode.

3. The semiconductor device according to claim 1, wherein the first conductive portion penetrates the first electrode, and the second conductive portion penetrates the second electrode.

4. (canceled)

5. The semiconductor device according to claim 1, further comprising:
a third electrode formed on the underlying film;
a second dielectric film formed on the third electrode; and
a fourth electrode formed on the second dielectric film,
wherein a side surface of the first conductive portion is in contact with the third electrode, and a side surface of the second conductive portion is in contact with the fourth electrode.

6. The semiconductor device according to claim 5, wherein the first electrode and the third electrode are located within substantially the same plane and separated from each other, and the second electrode and the fourth electrode are located within substantially the same plane and separated from each other.

7. The semiconductor device according to claim 5, wherein the first electrode and the second electrode and the third electrode are located within substantially the same plane and formed of a common continuous conductive film, and the second electrode and the fourth electrode are located within substantially the same plane and formed of a common continuous conductive film.

8. The semiconductor device according to claim 1, further comprising:
a second dielectric film formed on the second electrode;
a third electrode formed on the second dielectric film;
a third dielectric film formed on the third electrode; and
a fourth electrode formed on the third dielectric film,
wherein a side surface of the first conductive portion is in contact with the third electrode, and a side surface of the second conductive portion is in contact with the fourth electrode.

9. The semiconductor device according to claim 8, wherein a pattern of the third electrode is substantially the same as a pattern of the first electrode, and a pattern of the fourth electrode is substantially the same as a pattern of the second electrode.

10. The semiconductor device according to claim 1, wherein the first dielectric film includes a ferroelectric film.

11-12. (canceled)

13. The semiconductor device according to claim 3, wherein the first conductive portion is in contact with an inner side surface of the first electrode, and the second conductive portion is in contact with an inner side surface of the second electrode.

14. A semiconductor device comprising:
a plurality of first electrodes stacked in a first direction;
a plurality of second electrodes stacked in the first direction, each of the second electrodes being interposed between adjacent ones of the first electrodes;
a plurality of dielectric films stacked in the first direction, each of the dielectric films being interposed between adjacent ones of the first and second electrodes; and
a first interconnect including a first conductive portion extending in the first direction, a side surface of the first conductive portion being in contact with each of the first electrodes,
a second interconnect including a second conductive portion extending in the first direction, a side surface of the second conductive portion being in contact with each of the second electrodes.

15. The semiconductor device according to claim 14, wherein the first conductive portion is in contact with a side surface and a top surface of each of the first electrodes, and the second conductive portion is in contact with a side surface and a top surface of each of the second electrodes.

16. The semiconductor device according to claim 14, wherein the first conductive portion penetrates each of the first electrodes, and the second conductive portion penetrates each of the second electrodes.

17. The semiconductor device according to claim 14, wherein the first electrodes have substantially the same pattern, and the second electrodes have substantially the same pattern.

18. The semiconductor device according to claim 14, wherein each of the dielectric films includes a ferroelectric film.

19. The semiconductor device according to claim 16, wherein the first conductive portion is in contact with an inner side surface of each of the first electrodes, and the second conductive portion is in contact with an inner side surface of each of the second electrodes.
